(19) United States
(12) Patent Application Publication
(10) Pub. No.: US 2011/0239096 A1
(43) Pub. Date: Sep. 29, 2011

(54) DATA MEMORY DEVICE AND METHOD OF PROGRAMMING TO THE SAME

(75) Inventor: Hidefumi NAWATA, Kawasaki-shi (JP)

(73) Assignee: KABUSHIKI KAISHA TOSHIBA, Tokyo (JP)

(21) Appl. No.: 12/884,882

(22) Filed: Sep. 17, 2010

(30) Foreign Application Priority Data
Mar. 25, 2010 (JP) 2010-069212

(51) Int. Cl. G06F 12/00; H03M 13/09; G06F 11/10

(52) U.S. Cl. 714/801; 711/154; 711/E12.001; 714/E11.034

(57) ABSTRACT

A memory element array includes plural memory elements capable of storing M-value data (M is a natural number not smaller than 2). Among first to M-th data, the first data gives a largest physical impact on memory elements.

A data processing unit can execute a data process on an aggregate of program data stored in a data storing unit. It is determined that which of the first to the M-th data is least existing data, the number of pieces of which is the smallest in the aggregate of the program data. When the least existing data is other than the first data, the least existing data in the aggregate of program data is replaced with the first data, and the first data with the least existing data.

When the least existing data is the first data, the aggregate of program data is maintained without any data replacement.

### CROSS REFERENCE TO RELATED APPLICATIONS

This application is based on and claims the benefit of priority from prior Japanese Patent Application No. 2010-69212, filed on Mar. 25, 2010, the entire contents of which are incorporated herein by reference.

### BACKGROUND

1. Field

Embodiments described herein relate generally to a data memory device and a method of programming data into a data memory device.

2. Description of Related Art

Various types of devices have been proposed as nonvolatile semiconductor memory devices that store data in a memory cell in a nonvolatile manner. Among them, a NAND type flash memory is widely used as a data storage device because it is easy to increase their memory capacity.

The cell array of a NAND type flash memory is constructed as an array of NAND cell units. Each of the NAND cell units includes a plurality of memory cells connected in series. Both ends of each NAND cell unit are connected to a bit line and a source line respectively via select gate transistors.

Control gates of the memory cells in a NAND cell unit are connected to different word lines respectively. In the NAND type flash memory, a plurality of memory cells are connected in series such that they share sources and drains among them and also share select gate transistors as well as a bit line contact and a source line contact of the select gate transistors. Therefore, it is possible to reduce the size of the unit memory cell of the NAND type flash memory. Further, the NAND type flash memory is suitable for shrinking because the shapes of the word lines and of the device area of the memory cells are similar to a simple stripe shape, which contributes to realization of flash memories with a large memory capacity.

Data programming and erasing to the NAND type flash memory are executed by making a FN tunnel current flow through many cells simultaneously. Specifically, an aggregate of memory cells sharing one word line constitute one page or two pages. Then, data programming is executed on a page basis. Data erasing is executed on a block basis where a block is defined by an aggregate of NAND cell units sharing word lines and select gate lines.

Here, repetitive programming and erasing to one memory cell give rise to a problem that the tunnel insulating film of the memory cell gradually degenerates and the reliability of the memory decreases.

Therefore, a stress to be given on a memory cell by a programming voltage and an erasing voltage should be reduced as much as possible. Reduction of a stress on a memory cell increases the reliability of the memory and contributes to prolongation of the life of the memory cell.

### BRIEF DESCRIPTION OF THE DRAWINGS

FIG. 1 shows main functional blocks of a memory card including a nonvolatile semiconductor memory device (NAND cell type flash memory) according to a first embodiment of the present invention.

FIG. 2A shows a functional block configuration of a memory card 2000 of FIG. 1, wherein logic controls of a memory 21 and a controller 22 are combined.

FIG. 2B is a functional block diagram of a control circuit 6 of FIG. 2A.

FIG. 2C is a conceptual diagram showing a function of a data dividing process unit 216 shown in FIG. 2B.

FIG. 3 shows a cell array configuration of a memory cell array in the memory 21 of FIG. 1.

FIG. 4 shows a cross sectional structure of a memory cell MC.

FIG. 5 shows a cross sectional structure of select gates S1 and S2.

FIG. 6 shows a cross sectional structure of a NAND cell unit NU.

FIG. 7 is a conceptual diagram for explaining a case of implementing a two-value storage scheme of storing two-value data (M=2), i.e., one-bit data per one memory cell.

FIG. 8 is a conceptual diagram for explaining a case of implementing a four-value storage scheme of storing four-value data (M=4), i.e., two-bit data per one memory cell.

FIG. 9 is a conceptual diagram for explaining a case of implementing a four-value storage scheme of storing four-value data (M=4), i.e., two-bit data per one memory cell.

FIG. 10 is a conceptual diagram for explaining a case of implementing a four-value storage scheme of storing four-value data (M=4), i.e., two-bit data per one memory cell.

FIG. 11 shows how threshold voltages of memory cells Mc fluctuate due to inter-cell interference.

FIG. 12A shows how threshold voltages of memory cells Mc fluctuate due to inter-cell interference.

FIG. 12B shows how threshold voltages of memory cells Mc fluctuate due to inter-cell interference.

FIG. 13A is a flowchart showing an operation according to the first embodiment.

FIG. 13B shows a flowchart showing another example of the operation according to the first embodiment.

FIG. 14 shows an operation of data replacement for when the two-value storage scheme is implemented.

FIG. 15 shows an operation of data replacement for when the four-value storage scheme is implemented.

FIG. 16 is a flowchart showing an operation according to a second embodiment.

### DETAILED DESCRIPTION

A data memory device according to one embodiment of the present invention comprises a memory element array including an array of a plurality of memory elements each capable of storing M-value data (where M is a natural number not smaller than 2), a data storing unit configured to temporarily store data (program data) to be programmed into the memory elements, and a data processing unit configured to execute a data process on the program data. Among first data to M-th data constituting the M-value data, the first data is the data that gives the largest physical impact on the memory cells when programmed.

The data processing unit is configured to be capable of executing a data process on an aggregate of program data stored in the data storing unit as data to be programmed into memory elements included in an aggregate of a plurality of the memory elements. In the data process, it is determined which of the first data to the M-th data is least existing data, the number of pieces of the least existing data being the smallest in the aggregate of the program data.

When the least existing data is other than the first data, each of the least existing data included in the aggregate of program data is replaced with the first data. On the other hand, each of the first data included in the aggregate of program data is replaced with the least existing data.

When the least existing data is the first data, the aggregate of program data is maintained as it is without any data replacement thereon.

Next, the embodiments of the present invention will be explained in detail with reference to the drawings.

### First Embodiment

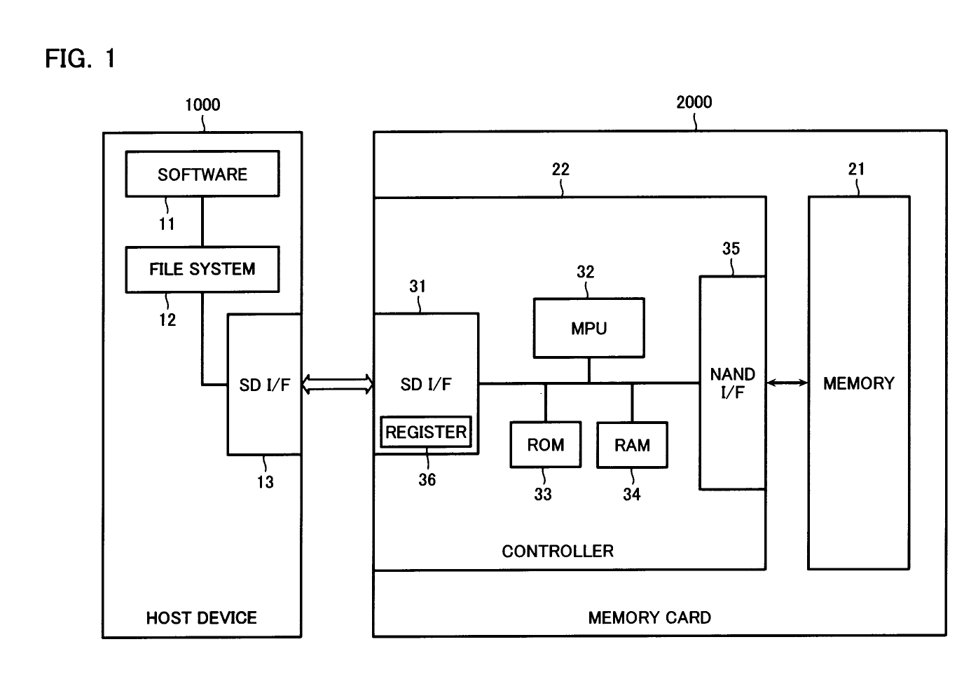

First, a nonvolatile device according to a first embodiment of the present invention will be explained with reference to FIG. 1, etc.

FIG. 1 shows main functional blocks of a memory card including a nonvolatile semiconductor memory device (NAND cell type flash memory) according to the first embodiment of the present invention. FIG. 1 also shows functional blocks of a host device connected to the memory card. Each functional block can be realized either as hardware, computer software or a combination of hardware and computer software. Therefore, in order to clarify that each of the functional blocks can take any form, these blocks will be explained below mainly in terms of their functions. Whether these functions shall be implemented by hardware or software depends on design constraints imposed on specific embodiments of these functional blocks or those imposed on the whole system. Although those skilled in the art could implement these functions under various types of implementation schemes depending on specific embodiment thereof, any such implementation scheme will be included in the scope of the present invention.

A host device (hereinafter, referred to as host) 1000 includes software 11 such as an application, an operating system, etc. The software 11 is instructed by a user to program data into a memory card 2000 or read data from the memory card 2000. The software 11 instructs a file system 12 to execute data programming or reading. The file system 12 is a mechanism for managing file data stored in a storage medium as an object of the control management. The file system 12 records management information in a memory area of the memory medium, and manages the file data by using the management information.

The host 1000 includes an SD interface 13. The SD interface 13 is composed of hardware and software necessary for executing interface processes between the host 1000 and the memory card 2000. The host 1000 communicates with the memory card 2000 via the SD interface 13. The SD interface 13 prescribes various rules necessary for the host 1000 and the memory card 2000 to communicate and has various command sets recognizable mutually by the SD interface 13 and by an SD interface 31 of the memory card 2000 to be described later. The SD interface 13 also includes hardware configuration (the arrangement and the number of pins, etc.) that can be connected to the SD interface 31 of the memory card 2000.

The memory card 2000 includes a NAND type flash memory 21 and a controller 22 for controlling the memory 21. The memory card 2000 executes a process corresponding to an access by the host 1000 when it is connected to the host 1000, or when it is first connected to the host 1000 in an OFF state, and then the host 1000 is turned on and finishes an initialization operation with a power source supplied thereto.

The memory 21 stores data in a nonvolatile manner, and has data written thereinto or read out therefrom on the basis of a page composed of a plurality of memory cells. Each page is assigned a physical address unique to the page. The memory 21 has data erased therefrom on the basis of a physical block (erase block) composed of a plurality of pages. In some cases, physical addresses are assigned on the physical block basis.

The controller 22 manages the state of data storage in the memory 21. The management of the state of data storage includes management of information about which physical-address page (or physical block) retains which logical-address data, and management of information about which physical-address page (or physical block) is in an erased state (a state where no data is written therein, or a state where invalid data is stored therein).

The controller 22 includes an SD interface 31, an MPU (Micro Processing Unit) 32, a ROM (Read Only Memory) 33, a RAM (Random Access Memory) 34, and a NAND interface 35.

The SD interface 31 is composed of hardware and software necessary for executing interface processes between the host 1000 and the controller 22. Like the SD interface 13, the SD interface 31 prescribes rules for enabling communication between the host 1000 and the controller 22, has various command sets, and includes hardware configuration (the arrangement and the number of pins, etc.) The memory card 2000 (controller 22) communicates with the host 1000 via the SD interface 31. The SD interface 31 includes a register 36.

The MPU 32 controls the operation of the entire memory card 2000. The MPU 32 loads firmware (a control program) stored in the ROM 33 into the RAM 34 and executes a certain process, when, for example, the memory card 2000 receives power supply. The MPU 32 generates various tables (described later) in the RAM 34 in accordance with the control program, and executes a certain process on the memory 21 in accordance with a command from the host 1000.

The ROM 33 stores the control program and the like to be controlled by the MPU 32. The RAM 34 is used as a work area of the MPU 32, and temporarily stores the control program and various tables. Such tables include a translation table (logical/physical address translation table) for translating a logical address assigned to data by the file system 12 into a physical address of the page that actually stores the data. The NAND interface 35 executes interface processes between the controller 22 and the memory 21.

In correspondence with types of data to be stored, the memory area in the memory 21 includes, for example, a system data area, a confidential data area, a protected data area, a user data area, etc. The system data area is an area secured by the controller 22 in the memory 21 in order to store data necessary for the operation of the controller 22. The confidential data area stores key information used for encryption and confidential data used for authentication, and is inaccessible by the host 1000. The protected data area stores important data and secure data. The user data area is freely accessible and usable by the host 1000, and stores user data such as an AV content file and image data, etc. Where the following explanation uses the term “memory 21” to mean “a memory space” in the memory 21, the term refers to the user data area. The controller 22 secures part of the user data area to store control data (a logical address/physical address correspondence table, etc.) necessary for its operation.

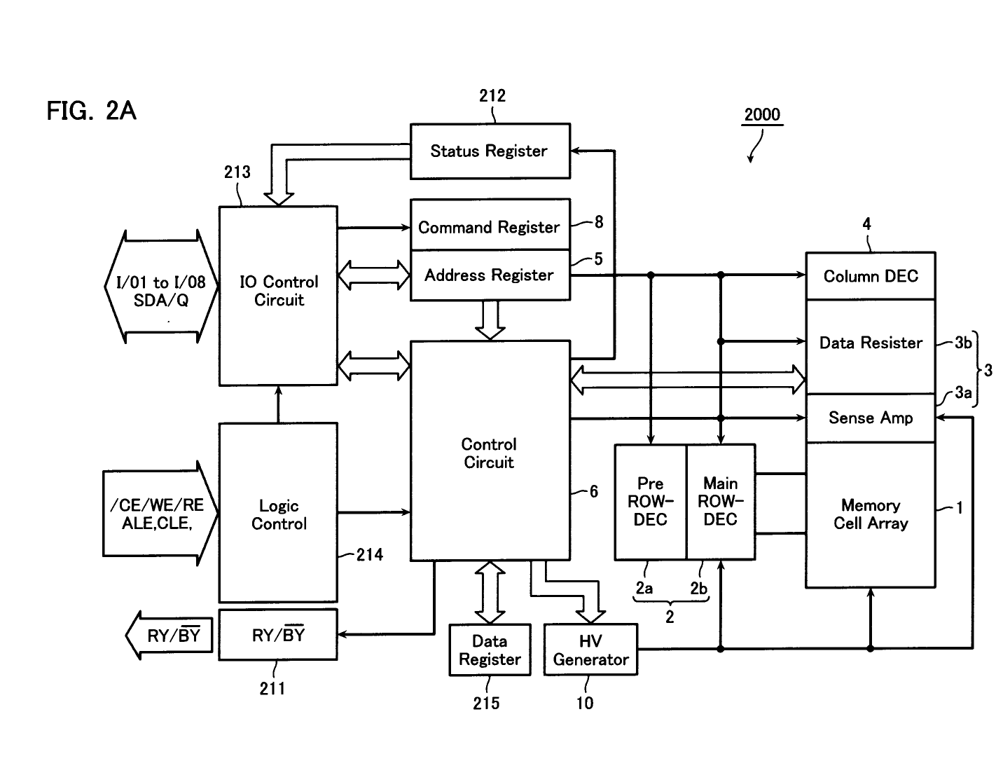

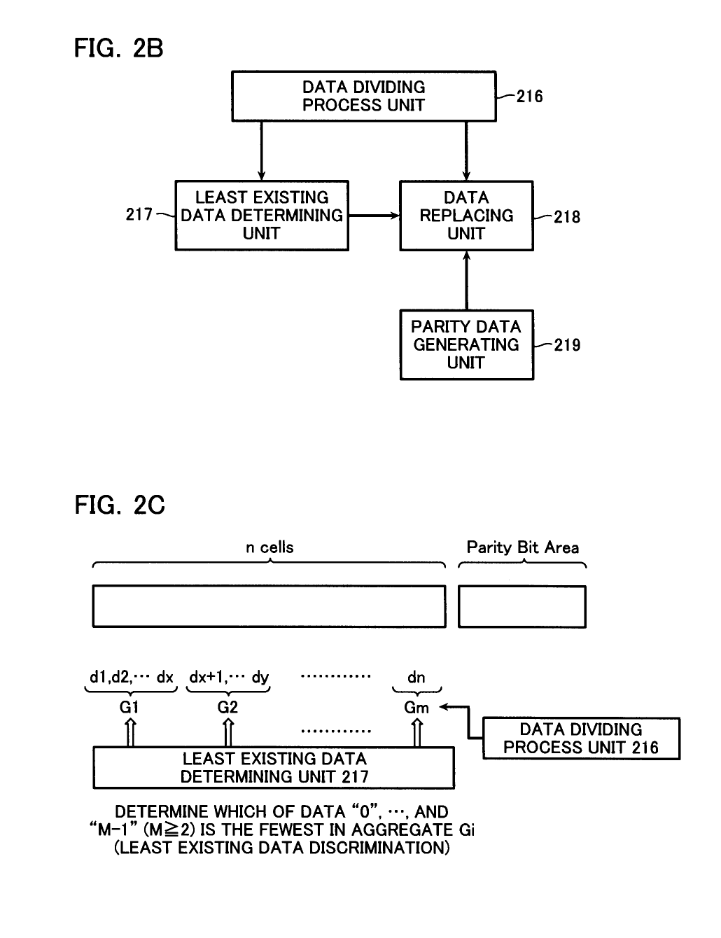

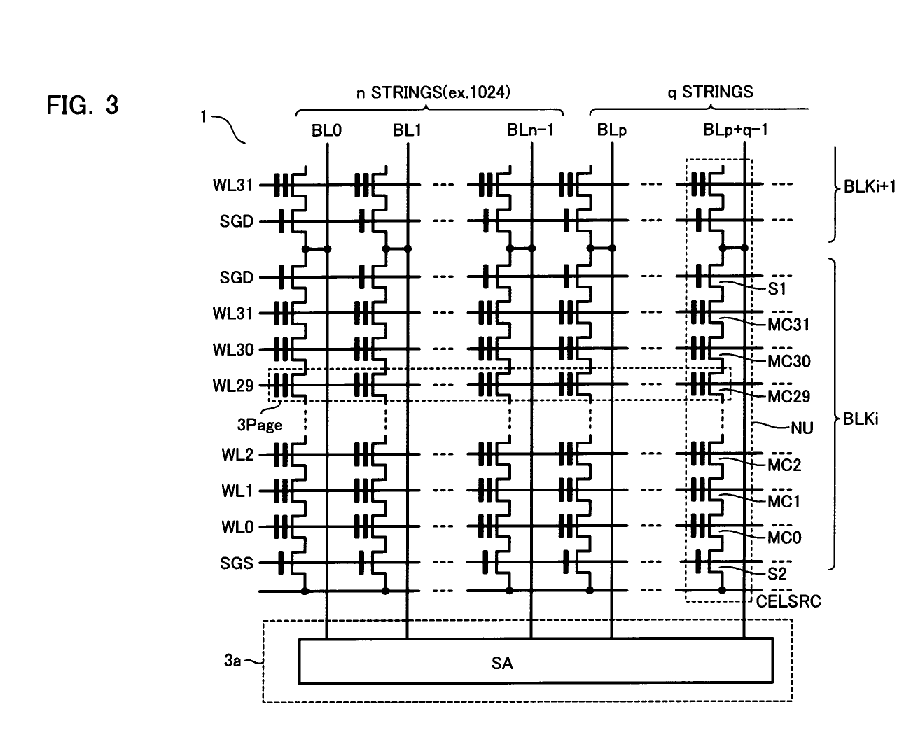

It is not essential for the present memory system that the memory card 2000 includes different chips for the memory and the controller 22 respectively. FIG. 2A shows a functional block configuration of the memory card 2000 of FIG. 1, where the logic controls of the memory 21 and the controller 22 are combined. FIG. 2B is a functional block diagram of a control circuit 6 in the FIG. 2A. FIG. 2C is a conceptual diagram showing a function of a data dividing process unit 216 shown in FIG. 2B. FIG. 3 shows a memory cell array configuration in the memory 21 of FIG. 1.

The memory card 2000 includes a memory cell array 1 (memory element array) composed of an arrangement of a plurality of memory cells MC (memory elements). As shown in FIG. 3, the memory cell array 1 is configured as an array of NAND cell units (NAND strings) NU each including a plurality of electrically rewritable nonvolatile memory cells (32 memory cells in the illustrated example) MC0 to MC31 connected in series. For example, 1024+q (n=1024) such NAND cell units NU share word lines WL and constitute one block BLK. As will be described later, the memory cells MC can each store M-value data (where M is a natural number not smaller than 2). For example, when M=4, i.e., one memory cell MC stores four-value data, the four-value data can be defined as data “3” (“11”), “2” (“01”), “1” (“10”), and “0” (“00”) respectively. Here, data programming is executed by applying a programming voltage, for example, 15 V to the word line WL and applying a voltage lower than the voltage applied to the word line WL, for example, 0 V to the bit lines BL.

Among the 1024+q NAND cell units NU, 1024 NAND cell units NU are used for storing effective data mainly supplied by the external host device. Meanwhile, the remaining “q” NAND cell units are used as a memory area for storing parity data described later. The parity data indicates whether data replacement to be described later has been executed or not, and when data replacement has been executed, the type of data that has been the target of data replacement among the M-value data. As will be described later, data replacement is executed in a manner that a physical impact to be given on the memory cells MC can be as small as possible in the whole memory cell array in total, specifically in a manner that as many memory cells MC as possible can be maintained in an erased state.

One block BLK constitutes a unit of a data erasing operation. When one memory cell MC stores two-bit data (two bits per cell), the memory cells MC formed along one word line WL store data amounting to two pages (an upper page UPPER and a lower page LOWER).

As shown in FIG. 3, one end of a NAND cell unit NU is connected to a bit line BL via a select gate transistor S1 and the other end thereof is connected to a common source line CELSRC via a select gate transistor S2. The control gates of the memory cells M0 to M31 are connected to the word lines WL0 to WL31 respectively, and the gates of the select gate transistors S1 and S2 are connected to the select gate lines SGD and SGS respectively.

A sense amplifier circuit 3a used for reading and programming of cell data is disposed at one end side of the bit lines BL, and a row decoder 2 (not illustrated in FIG. 3) that selectively drives the word lines and select gate lines is disposed at one end side of the word lines WL. The row decoder 2 includes a pre row decoder 2a that specifies one of a plurality of blocks, and a main row decoder 2b that selectively drives one word line WL in one block.

A command, an address, and data are input through an IO control circuit 213, and a chip enable signal /CE, a write enable signal /WE, a read enable signal /RE, and other external control signals are input into a logic control circuit 214 and used for timing control. A command is decoded by a command register 8.

A control circuit 6 executes data transfer control and sequence control for programming/erasing/reading. A status register 211 outputs a Ready/Busy status of the memory card 2000 to a Ready/Busy terminal. Aside from this, a status register 212 is prepared that notifies the status (Pass/Fail, Ready/Busy, etc.) of the memory 2000 to the host 1000 via an I/O port.

An address is transferred via an address register 5 to the row decoder (the pre row decoder 2a and the main row decoder 2b) 2 and a column decoder 4. Program data is once stored temporarily in a data register 215 via the I/O control circuit 213 and the control circuit 6, and then subjected to data replacement to be described later. The program data after data replacement is loaded into the sense amplifier circuit 3 (a sense amplifier 3a and a data register 3b) to become the target of programming. Read data is externally output via the control circuit 6.

A high voltage generator 10 is provided for generating a high voltage necessary in accordance with each operation mode. The high voltage generator 10 generates a certain high voltage based on a command issued by the control circuit 6.

FIG. 2B is a functional block diagram of a data processing unit realized by the control circuit 6. As shown in FIG. 2B, the control circuit 6 is programmed to realize a data dividing process unit 216, a least existing data determining unit 217, a data replacing unit 218, and a parity data generating unit 219.

The data dividing process unit 216 has a function of dividing “n” number of program data (M-value data) d1, d2, . . . and dn temporarily stored in the data register 215 after supplied by the host 1000 to be programmed into “n” number of memory cells MC arranged along one word line WL in the memory cell array 1 into “m” number of data aggregates Gi (i=1 to m, m<n). Each of the plurality of data aggregates Gi includes plural pieces of M-value data di. The number of pieces of the M-value data di included in each of the aggregates Gi may be different among the aggregates Gi. Though it is preferable that the number of pieces of M-value data di included in each data aggregate Gi be an odd number, no problem will arise with an even number.

The number “m” of the data aggregates Gi is determined by weighing a demand for improving data reliability and reducing a cost per bit.

Where data di is M-value data, given data di is any of the data “0”, . . . , and “M−1”. In the present embodiment, it is assumed that the data “M−1” means data representing an erased state of a memory cell MC. On the other hand, the data “0” means data that will give the largest physical impact on a memory cell MC when it is programmed. In the present embodiment, as the memory cells MC are flash memories, the data “0” is defined as data that has the highest threshold voltage and hence the highest programming voltage is applied to the memory cell MC in order to be programmed. On the other hand, since the data “M−1” dose not require programming operation, it means data that will give the smallest physical impact on a memory cell MC.

The least existing data determining unit 217 has a function of determining types of “x” pieces of data di (M-value data) included in a given data aggregate Gi (i.e., determining which of the data “0”, . . . , and “M−1” is assigned for each of the “x” pieces of data di (M-value data)), and a function of determining which of the data “0”, . . . , and “M−1” is the fewest data (the least existing data) in the data aggregate Gi. The data replacing unit 218 is configured to be able to execute a first data process of replacing each least existing data with the data “0” when the least existing data specified by the least existing data determining unit 217 is other than the data “0”, and a second data process of maintaining the state of the data as it is without executing any data replacement when the least existing data is the data “0”.

The parity data generating unit 219 has a function of generating parity data corresponding to the least existing data when the first data process described above is executed by the data replacing unit 218.

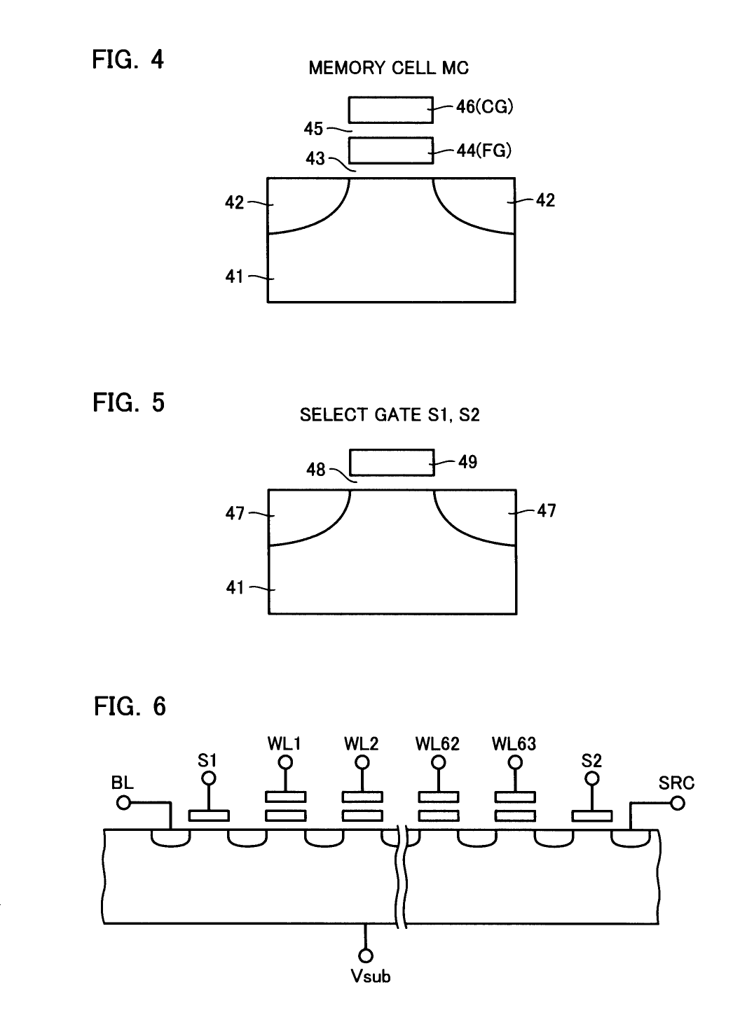

FIG. 4 and FIG. 5 show cross-sectional structures of a memory cell MC and the select gates S1 and S2. FIG. 4 shows a cross-sectional structure of a memory cell MC. Formed in a substrate 41 (or a p-type well) are n-type diffusion layers 42 that function as a source and drain of a MOSFET that constitutes the memory cell MC. A floating gate (FG) 44 is formed above the substrate 41 via a gate insulating film 43, and a control gate (CG) 46 is formed above the floating gate 44 via an insulating film 45. Instead of this so-called floating gate type memory cell, a MONOS type memory cell including a charge accumulation layer made of a silicon nitride film may be employed.

The select gates S1 and S2 include the substrate 41 and n-type diffusion layers 47 formed in the substrate 41 as their source and drain. A control gate 49 is formed above the substrate 41 via a gate insulating film 48.

FIG. 6 shows a cross section of one NAND cell in the memory cell array 1. In this example, one NAND cell is composed of series-connected thirty-two memory cells MC each having the structure shown in FIG. 4. The first select gate S1 and second select gate S2 having the structure shown in FIG. 5 are provided at the drain and source sides of the NAND cell respectively.

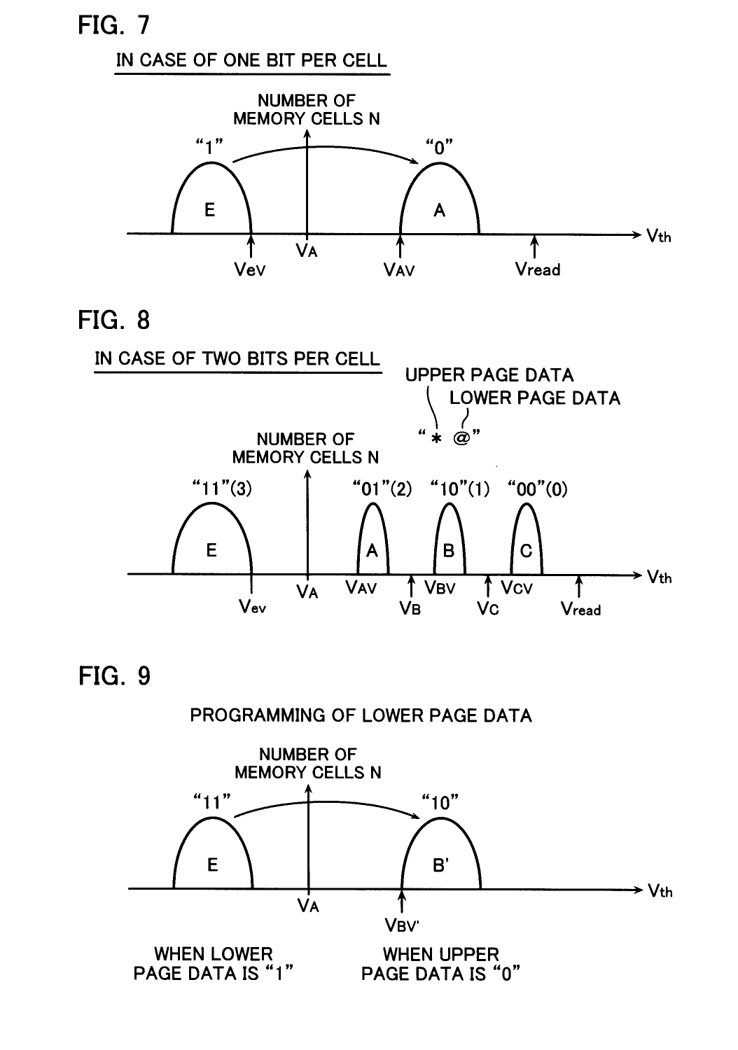

Next, a case of implementing a two-value storage scheme of storing two-value data (M=2), i.e., one-bit data per memory cell in the present embodiment will be explained with reference to FIG. 7. In the case of the two-value storage scheme, either data “1” or “0” is stored in a memory cell MC. In this case, the NAND type flash memory is configured such that the threshold voltage of one memory cell MC can have two threshold voltage distributions E and A. FIG. 7 shows a relationship between one-bit two-value data (data “1”, “0”) stored in the memory cells of a two-value storage type NAND cell type flash memory and the threshold voltage distributions E and A of the memory cells. Hereinafter, when it is said that “a threshold distribution is high or low”, whether it is high or low is determined based on whether its peak is high or low, unless otherwise specified.

In FIG. 7, a voltage V_{A} is a voltage to be applied to a selected word line for reading the two types of data “1” and “0”, and V_{A}=0V, for example. A voltage V_{AV} indicates a verify voltage to be applied in programming of the threshold voltage distribution A in order to confirm whether the programming has been completed or not. A voltage V_{read} indicates a reading voltage to be applied to non-selected memory cells in the NAND cell during a data reading operation to make the non-selected memory cells electrically conductive regardless of the data stored therein. A voltage Vₑᵥ is an erase verify voltage to be applied to the memory cells in erasing of data from the memory cells in order to confirm whether the erasing has been completed or not, and has a negative value, for example. The relationship of level among the above voltages is Vₑᵥ<V_{A}<V_{AV}<V_{read}.

Though the erase verify voltage Vₑᵥ is a negative value as described above, the voltage to be actually applied to the control gate of the memory cells MC during an erase verify operation is zero or a positive value and not a negative value. That is, in an actual erase verify operation, a positive voltage is supplied to the back gate of the memory cells MC and a zero voltage or a voltage having a positive value smaller than the back gate voltage is applied to the control gate of the memory cells MC. In other words, the erase verify voltage vₑᵥ is a voltage that equivalently has a negative value.

The threshold voltage distribution E of the memory cells after block basis erasing is entirely negative up to the upper limit thereof and is assigned the data “1”. Memory cells storing the data “0” representing a written state have the threshold voltage distribution A.

Next, an example of implementing a four-value storage scheme (M=4, two bits per cell) in an embodiment of the present invention will be explained with reference to FIG. 8 to FIG. 10.

A four-value NAND cell type flash memory is configured such that the threshold voltage of one memory cell MC can have four threshold voltage distributions E, A, B, and C. FIG. 8 shows a relationship between four-value data “11” (“3”), “01” (“2”), “10” (“1”), and “00” (“0”) stored in the memory cells of the four-value NAND cell type flash memory and the threshold voltage distributions E, A, B, and C of the memory cells MC. In FIG. 8, voltages V_{A}, V_{B}, and V_{C} are voltages to be applied to a selected word line for reading the four types of data (where the voltage V_{A} is 0 V), and voltages V_{AV}, V_{BV}, and V_{CV} indicate verify voltages to be applied in programming of the threshold voltage distributions E, A, B, and C for confirming whether the programming has been completed or not.

A voltage V_{read} indicates a reading voltage to be applied to non-selected memory cells in the NAND cell during a data reading operation to make the non-selected memory cells electrically conductive regardless of the data stored therein. A voltage Vₑᵥ is an erase verify voltage to be applied to the memory cells in erasing of data from the memory cells to confirm whether the erasing has been completed or not, and has a negative value, for example. The relationship of level among the above voltages is Vₑᵥ<V_{A}<V_{AV}<V_{B}<V_{BV}<V_{C}<V_{CV}<V_{read}.

The threshold voltage distribution E of the memory cells MC after block basis erasing is entirely negative (an upper limit of the threshold voltage distribution E is negative) and is assigned the data “11” (“3”). Memory cells MC storing the data “01” (“2”), “10” (“1”), and “00” (“0”) representing a programmed state have positive threshold voltage distributions A, B, and C respectively (the threshold voltage distributions A, B, and C are entirely positive, and each of a lower limit of the threshold voltage distributions A, B, and C is positive). The threshold voltage distribution A of the data “01” (“2”) has the lowest voltage value in the threshold voltage distribution A, B and C. The threshold voltage distribution C of the data “00” (“0”) has the highest voltage value. The threshold voltage distribution B of the data “10” (“1”) has a voltage value lying between the data “01” and the data “00”. The threshold voltage distributions shown in FIG. 8 are a mere example, and the present invention is not limited to this. For example, FIG. 8 illustrates that all of the threshold voltages A, B, and C are positive threshold voltage distributions, but the scope of the present invention also includes a case where the threshold voltage distribution A is a negative voltage distribution, and the threshold voltage distributions B and C are positive voltage distributions. The only requirement is that the threshold voltage distribution E should be a negative voltage distribution.

Two-bit data (four-value data) in one memory cell MC is composed of lower page data and upper page data. Lower page data and upper page data are programmed into a memory cell MC by different operations, i.e., by two programming operations. Where data is represented as “*@”, “*” represents upper page data and “@” represents lower page data.

First, programming of lower page data will be explained with reference to FIG. 9. Here, all the memory cells have the threshold voltage distribution E representing an erased state, which means that they store the data “11” (“3”). As shown in FIG. 9, when lower page data is programmed into the memory cells, the memory cells are divided into two threshold voltage distributions (E and B′) depending on the value (“1” or “0”) of the lower page data. That is, if the value of the lower page data is “1”, the memory cells maintain the threshold voltage distribution E representing an erased state.

On the other hand, if the value of the lower page data is “0”, a high electric field is applied to the tunnel oxide film of the memory cells to inject electrons into the floating gate electrode of the memory cells, to thereby raise the threshold voltage Vth of the memory cells by a certain amount. Specifically, a verify potential V_{BA}, is set, and programming is repeated until the threshold voltage of the memory cells becomes equal to or higher than the verify voltage V_{BV′}. As a result, the memory cells change to a written state (data “10” (“1”)).

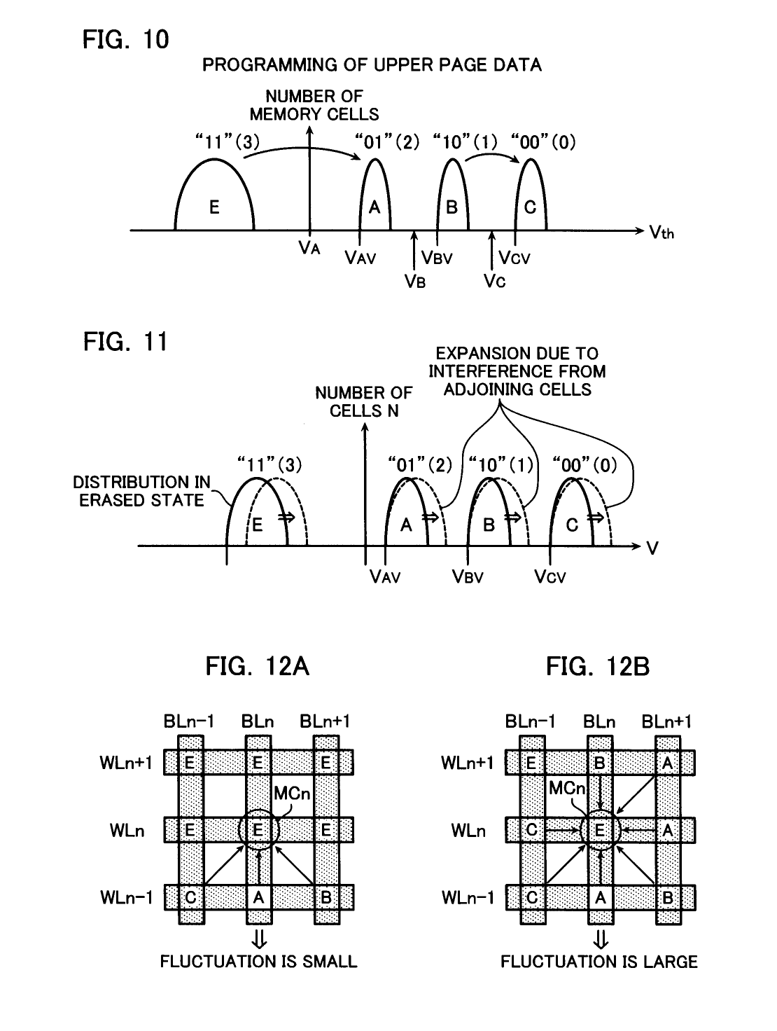

Next, programming of upper page data will be explained with reference to FIG. 10. Programming of upper page data is executed based on program data (upper page data) externally input from outside the chip, and the lower page data already programmed into the memory cells.

That is, as shown in FIG. 10, if the value of the upper page data is “1”, the threshold voltage Vth of the memory cells is prevented from rising, by avoiding a high electric field being applied to the tunnel oxide film of the memory cells. As a result, any memory cell that stores the data “11” (the threshold voltage distribution E representing an erased state) maintains the data “11” (“3”), and any memory cell that stores the data “10” (“1”) (the threshold voltage distribution B′) maintains the data “10” (“1”). However, the normal verify potential V_{BV} higher than the above verify voltage V_{BV′} is used to adjust the lower limit of the threshold voltage distribution to thereby form a threshold voltage distribution B having a smaller width of distribution.

On the other hand, if the value of the upper page data is “0”, a high electric field is applied to the tunnel oxide film of the memory cells to inject electrons into the floating gate electrode of the memory cells to thereby raise the threshold voltage Vth of the memory cells by a certain amount. As a result, any memory cell that stores the data “11” (“3”) (the threshold voltage distribution E representing an erased state) shifts to the data “01” (“2”) corresponding to the threshold voltage distribution A, and any memory cell that stores the data “10” (“1”) shifts to the data “00” (“0”) corresponding to the threshold voltage distribution C. At this time, the verify voltages V_{AV} and V_{CV} are used to adjust the lower limit of the threshold voltage distributions A and C.

The above is one example of data programming in a general four-value storage scheme. An operation of a multi-value storage scheme of three bits (eight-value) or more is basically the same as the above, because it only additionally includes dividing of the threshold voltage into eight distributions in accordance with the further upper page data.

The programming scheme may perform a writing operation that straightly achieve the threshold voltage distribution of the final target, or may perform a programming operation for programming another intermediate distribution (B′ of FIG. 9) different from the threshold voltage distribution as the final target.

When such two-value data or larger-value data (four-value, eight-value) is programmed into a memory cell MC, the higher the threshold voltage corresponding to that data is, the larger physical impact is given to the memory cell MC (degeneration of the gate insulating film is accelerated). Accordingly, when program data is externally supplied to a plurality of memory cells MC, it is desired that such externally-supplied program data form a data set in which the number of pieces of data “1” (in case of two-value data) or the number of pieces of data “11” (“3”) (in case of four-value data) to be provided to the memory cells MC is as large as possible, because such data will give a small physical impact to the memory cells.

When data corresponding to a high threshold voltage is to be written, not only the programming-target memory cell MC will be given a large physical impact, but the threshold voltages of adjoining memory cells that adjoin the programming-target memory cell MC fluctuate greatly due to inter-cell interference, which is deemed as a problem (see FIG. 11). This threshold fluctuation is smaller when many memory cells remain in the threshold voltage distribution E representing an erased state than when the threshold voltage distributions A, B, and C are written in many memory cells. That is, when many of the memory cells adjoining a memory cell MCn have the threshold voltage distribution E representing an erased state as shown in FIG. 12A, the memory cell MCn does not receive much influence from these adjoining memory cells and the threshold voltage of the memory cell MCn does not largely fluctuate. On the other hand, when many of the memory cells adjoining the memory cell MCn does not have the threshold voltage distribution E but the threshold voltage distributions A, B and C as shown in FIG. 12B, the memory cell MCn might receive influence from these adjoining memory cells and the threshold voltage of the memory cell MCn might largely fluctuate.

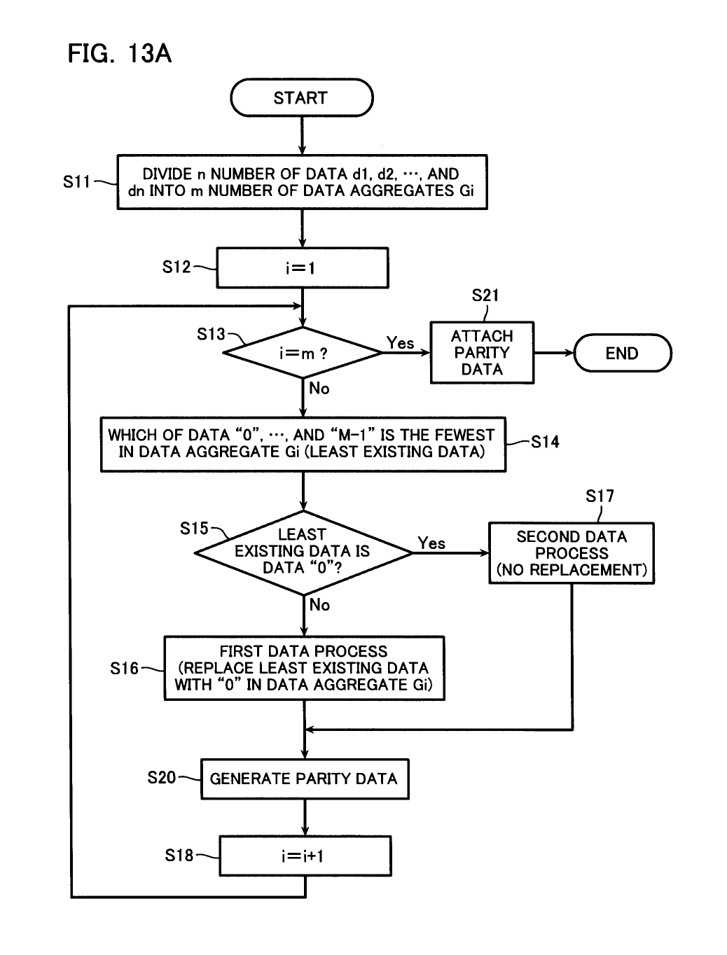

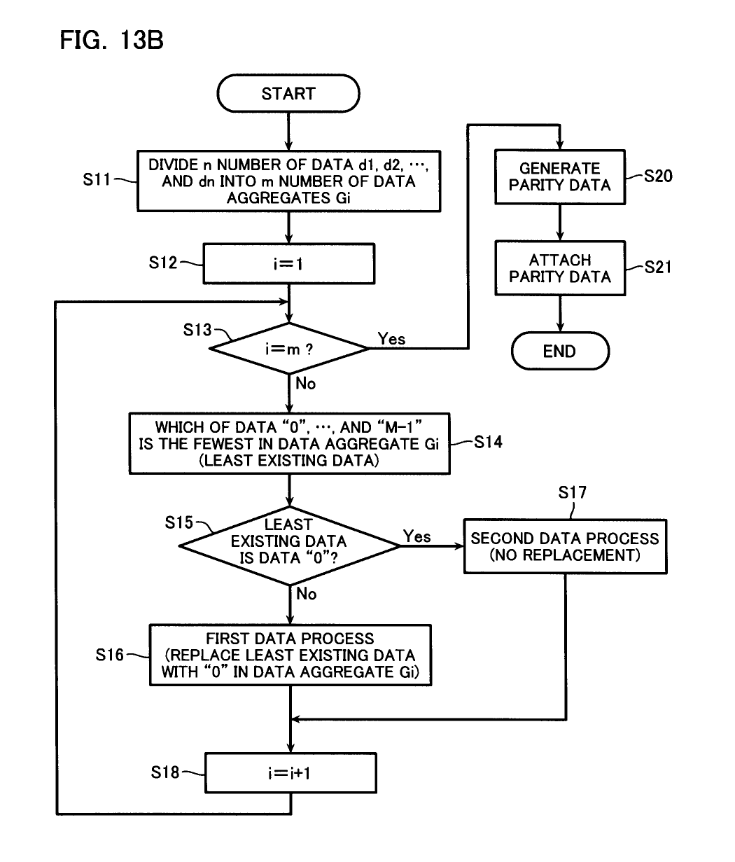

Hence, in the present embodiment, the following data process is executed. That is, data supplied by the host 1000 is subject to data replacement such that as many memory cells MC as possible are kept in the threshold voltage distribution E (or the state where the data “11” (“3”) is written is maintained). The operation of data replacement is executed by the data dividing process unit 216, the least existing data determining unit 217, and the data replacing unit 218. The operation of data replacement to be executed by the data dividing process unit 216, the least existing data determining unit 217, and the data replacing unit 218 will be explained with reference to FIG. 13A.

First, the data dividing process unit 216 divides “n” pieces of M-value data d1, d2, . . . , and dn, which is supplied from the host 1000 to be programmed into “n” pieces of memory cells MC arranged along one word line WL into “m” pieces of data aggregates Gi (i=1 to m) (step S11). Here, the data aggregate Gi is not limited to a data aggregate Gi composed of one page which is an aggregate of memory cells. For example, it may be a data aggregate Gi composed of three pages, or a data aggregate Gi composed of nine memory cells arranged in a matrix as shown in FIG. 12.

Next, i=1 is set (step S12). Then, it is determined whether i=m is satisfied or not (step S13). When step S13 results in NO, the least existing data determining unit 217 determines which of the data “0”, . . . , and “M−1” included in the data aggregate Gi is the least existing data (step S14). Note that, in Step S11, the number of pieces of M-value data di included in each data aggregate Gi may be set at an odd number. When two-value data storage is performed in this case, for example, either the data “0” or the data “1” is determined as the least existing data, which enables to effectively reduce a physical impact on the memory cells as much as possible.

When the least existing data is determined to be the data “0” (step S15; YES), the data aggregate Gi concerned is not subjected to data replacement and the data in the data aggregate Gi is maintained as it has been when transferred from the host 1000 (step S17: second data process).

In contrast, when the least existing data is determined to be the data “1” (step S15; NO), data replacement is executed to replace each least existing data in the data aggregate Gi with the data “0” and each data “0” in the data aggregate Gi with the least existing data (step S16: first data process). After this, parity data corresponding to the replaced data is generated (step S20), and “i” is incremented (step S18). The above operation is repeated until “i” reaches “m”.

When “i” has reaches “m”, the parity data generated at step S20 is attached to the data aggregates Gi (step S21), and the process is completed. Generating and attaching the parity data in this manner is effective when the number of data aggregates Gi is small or when the capacity of the cache memory (e.g., the RAM 34) is small.

FIG. 13B is a flowchart showing another operation example according to the first embodiment. As shown in FIG. 13B, the operation of generating parity data (step S20) and the operation of attaching the parity data generated at step S20 to the data aggregate Gi (step S21) may be executed continuously after a “YES” determination is done at step S13. Generating and attaching the parity data in this manner is effective when the number of data aggregates Gi is large or when the capacity of the cache memory (e.g., the RAM 34) is large.

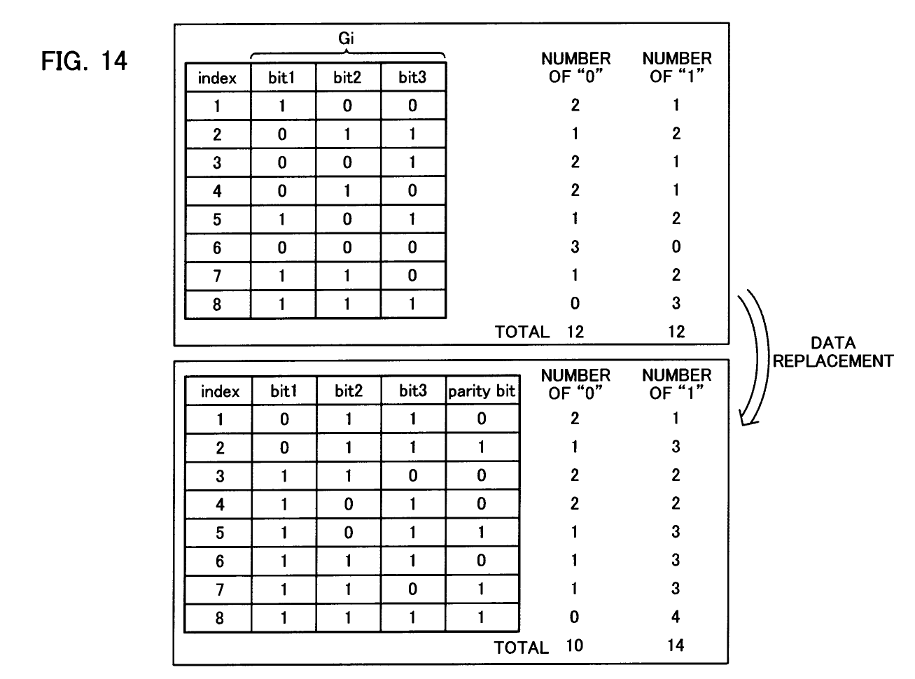

FIG. 14 explains an operation of data replacement for when two-value data (“1” or “0”) is programmed into one memory cell MC and a data aggregate Gi includes three pieces of two-value data bit1 to 3. This is a mere example, and it will be understood from the following explanation that data replacement can be executed in a similar manner when a data aggregate Gi includes four or more pieces of data. In FIG. 14, indexes 1 to 8 show combinations of the three pieces of two-value data bit1 to 3.

In this case, the least existing data determining unit 217 determines the type of the three pieces of two-value data bit1 to 3 included in a data aggregate Gi (whether the type is “1” or “0”) to determine which of “0” and “1” exists less (or the least) in the data aggregate Gi. That is, which of “0” and “1” is the least existing data is determined.

When the least existing data determined by the least existing data determining unit 217 is the data “1” and is not the data “0”, the data replacing unit 218 executes the first data process of data replacement of the least existing data “1” and the data “0” in the data aggregate Gi. To the contrary, when the least existing data is the data “0”, the data replacing unit 218 executes the second data process of maintaining the data as they are by not executing data replacement. Then, when the executed process is the first data process, the parity data generating unit 219 generates data “0” as parity data, and attaches the generated data to the data aggregate Gi. Conversely, when the executed process is not the first data process but the second data process (when no data replacement has been executed), the parity data generating unit 219 generates data “1” as parity data, and attaches the generated data to the data aggregate Gi. The generated parity data are stored in those memory cells constituting a parity data storing unit (“q” NAND cell units NU shown in FIG. 3).

An effect obtained by executing this operation in the case of two-value data storage is explained in FIG. 14. FIG. 14 describes all cases where three memory cells (“bit1”, “bit2”, and “bit3”) each store either “0” or “1”. Serial numbers are assigned to these cases as indexes. There are eight cases in which the three memory cells each store either data “0” or “1”. The total numbers of “0” and “1” in all of the cases are calculated, and shown in the section of “TOTAL”. As shown in the section of “TOTAL” of FIG. 14, the number of data “0” in the program data can be reduced compared to the number of data “0” before data replacement is executed (before the first data process or the second data process is executed), even if the parity data is taken into consideration. That is, the number of the data “0” can be reduced from 12 to 10. Accordingly, it is possible to reduce a physical impact to be given on the memory cells MC relatively, and as a result to improve the reliability of the memory and contribute to prolongation of the life of the memory.

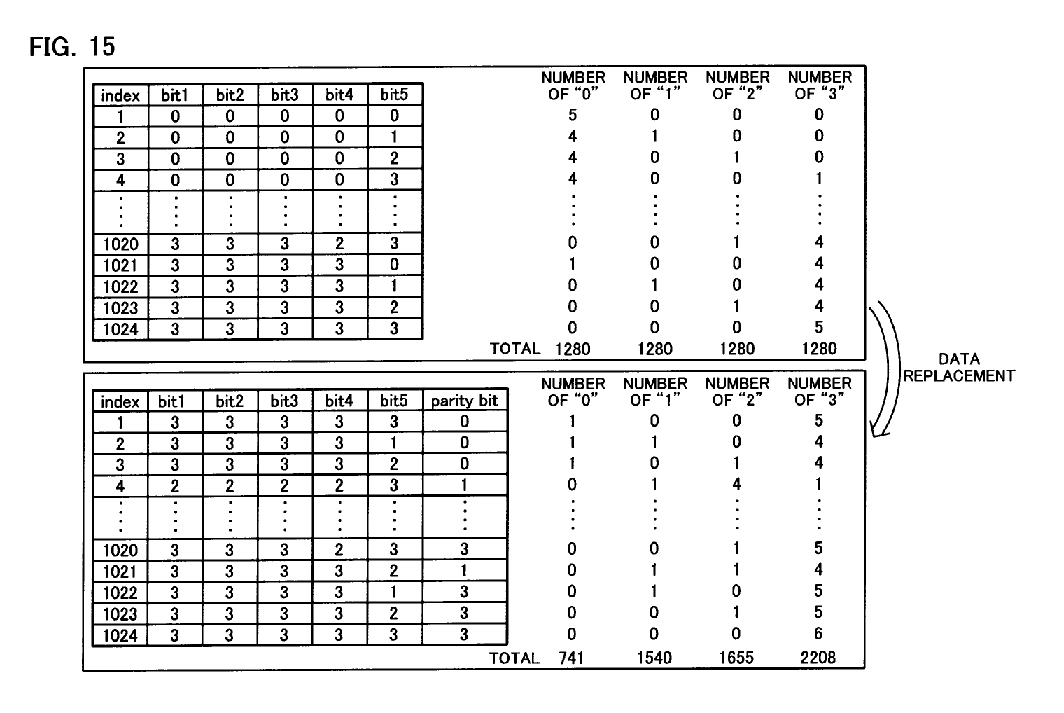

FIG. 15 explains an operation of data replacement when four-value data (data “11” (“3”), “01” (“2”), “10” (“1”), and “00” (“0”)) is programmed into one memory cell MC and a data aggregate Gi includes five pieces of four-value data bit1 to 5. FIG. 15 describes all cases where five memory cells (“bit1”, “bit2”, “bit3”, “bit4”, and “bit5”) each store “0”, “1”, “2”, or “3”. Serial numbers are assigned to these cases as indexes. There are 1024 cases in total in which the five memory cells each store any of the data “0” to “3”. The total numbers of each of “0” to “3” in all of the cases are calculated, and shown in the section of “TOTAL”.

Also in this case too, like in FIG. 14, an operation of determining the least existing data by the least existing data determining unit 217 and replacing the specified least existing data with the data “00” (“0”) in a data aggregate Gi is executed. When two or more types of data correspond to the least existing data, least existing data is selected such that the data “00” (“0”) is replaced with data that will give a smaller physical impact on the memory cells MC. For example, in the index 1 of FIG. 15, all of the data bit1 to 5 are data “0”, and the least existing data is hence data “3”, data “2”, and data “1”. In this case, the data “3” that gives the smallest physical impact on the memory cells MC is selected as the least existing data and data replacement is executed between data “3” and data “0”.

When the data “0” and other data both correspond to the least existing data, data replacement is executed by defining the data “0” as the least existing data. For example, in the index 1022 of FIG. 15 where the least existing data is data “0” and data “2”, data “0” is defined as the least existing data. As a result, the first data process is not executed for the index 1022, and data replacement is not executed (the second data process is executed). Hence, it is possible to effectively reduce a physical impact to be given on the memory cells. The operation of data replacement in FIG. 15 can be summarized as follows.
(1) When the least existing data in a data aggregate Gi is the data “00” (“0”), the first data process is not executed on the data bit1 to 5 in the data aggregate Gi (data replacement is not executed), but the second data process is executed. Data “11” (“3”) is generated and attached as parity data.
(2) When the least existing data in a data aggregate Gi is the data “10” (“1”), an operation of replacing the data “00” (“0”) and the data “10” (“1”) that is determined as the least existing data (first data process) is executed on the data bit1 to 5 in the data aggregate Gi. Data “01” (“2”) is generated and attached as parity data.
(3) When the least existing data in a data aggregate Gi is the data “01” (“2”), an operation of replacing the data “00” (“0”) and the data “01” (“2”) as the least existing data (first data process) is executed on the data bit1 to 5 in the data aggregate Gi. Data “10” (“1”) is generated and attached as parity data.
(4) When the least existing data in a data aggregate Gi is the data “11” (“3”), an operation of replacing the data “00” (“0”) and the data “11” (“3”) as the least existing data (first data process) is executed on the data bit1 to 5 in the data aggregate Gi. Data “00” (“0”) is generated and attached as parity data.

As shown in the section of “TOTAL” of FIG. 15, like in FIG. 14, it is possible to reduce the number of the data “00” (“0”) even if the parity data is “00” (“0”) is taken into consideration (from 1280 to 741).

In the examples (FIG. 14 and FIG. 15) presented above, it is defined that in a data aggregate Gi including pieces of M-value data, the M-th data is the data corresponding to the lowest threshold voltage (the smallest physical impact on the memory cells), and the (M−1)th data, the (M−2)th data, . . . correspond to higher threshold voltages in this order, so the first data is the data corresponding to the highest threshold voltage. In this case, when the target data of data replacement is P-th data (where 1<P<M), (M−P+1)th data is attached as parity data. This enables to make the number of pieces of data “0” be the fewest in the program data including parity data.

Data having a high threshold distribution, e.g., a high programming voltage is applied to a memory cell when the data “0” in the four-value data is programmed into a memory cell. Here, by applying the present invention, it is possible to reduce the number pieces of data corresponding to a high threshold distribution and reduce power consumption.

In the first embodiment of the present invention, it is possible to restore the data in a data reading operation easily by using the parity data. For example, when the parity data is “0”, it is only necessary to replace the data “3” and the data “0” among the pieces of data stored in the memory cells. Likewise, when the parity data is “1”, it is only necessary to replace the data “2” and the data “0” among the pieces of data stored in the memory cells. When the parity data is “2”, it is only necessary to replace the data “1” and the data “0” among the pieces of data stored in the memory cells. When the parity data is “3”, no data replacement is executed among the pieces of data stored in the memory cells. That is, data as a target of data replacement is replaced with the data “0” that will give the largest physical impact on the memory cells. The parity data suggests the type of the data to be replaced with the data “0” that will give the largest physical impact on the memory cells.

As is clear, the data restoration according to the first embodiment of the present invention is a simple operation. It does not require any complicated operation such as plural replacement of the data that will give a physical impact. Hence, the data restoration can be accelerated.

### Second Embodiment

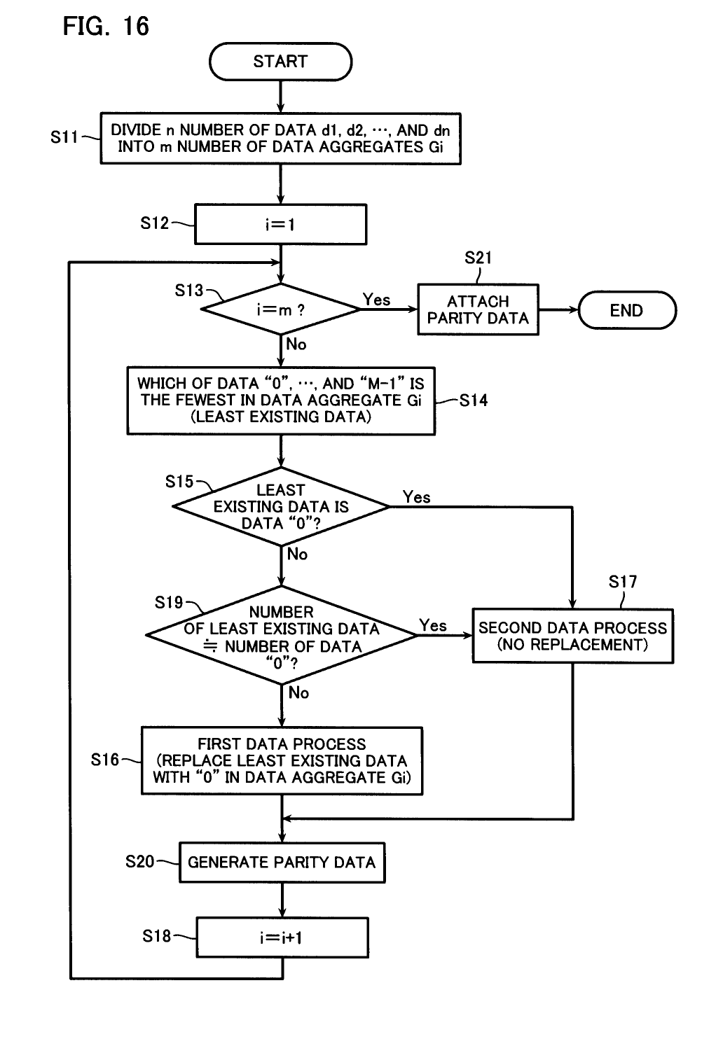

Next, a second embodiment of the present invention will be explained with reference to FIG. 16. Since the configuration of the present embodiment may be the same as that of the first embodiment (FIG. 1 to FIG. 3), a detailed explanation thereof will not be provided. In the present embodiment, the operations of the least existing data determining unit 217 and data replacing unit 218 are different from those of the first embodiment. The operations according to the second embodiment will be explained with reference to FIG. 16.

The difference in operation is that after it is determined at step S15 that the least existing data is data other than the data “0”, determination is made whether the number of pieces of the least existing data is approximately equal to the number of pieces of the data “0” (step S19). When both the numbers are approximately equal, which means that the effect of data replacement is very limited, the flow goes to the second data process in which data replacement is not executed (step S17). This can avoid an unnecessary operation of data replacement from being executed and improve the operation speed of the memory device. Further, since parity data to be attached when the flow goes to step S17 is the data “3” representing an erased state, power consumption can be reduced.

It is also possible in FIG. 16 to change the operation procedure such that parity data is generated and attached according to the procedure shown in FIG. 13B.

### Others

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions. For example, though the above embodiments have been explained by employing a NAND type flash memory as an example, it is apparent from the above given explanation that the present invention can be widely applied to data memory devices that store data in a memory element by imposing a physical impact on the memory element.

Further, in the embodiments described above, an example has been explained in which the operation of data replacement is executed by the controller 22. The present invention is not limited to this, but the same function may be performed within the chip of the memory 21 or the host 1000 may execute the same operation.

Still further, in the embodiments described above, parity data is stored in an exclusive memory area for parity data different from a memory area for effective data. However, the present invention can also be applied to a storage scheme that stores parity data and effective data in the same memory area.

Furthermore, in the embodiments described above, an operation of dividing data to be stored in the memory cells arranged along one word line into a plurality of aggregates Gi is executed. The present invention is not limited to this, but various schemes of generating aggregates Gi are available. For example, in a memory device having a three-dimensional shape in which memories are stacked in the direction perpendicular to the substrate, it is possible to divide pieces of data to be programmed into a plurality of memory cells adjoining one another in the directions of the three dimensions into a plurality of aggregates to execute the same data processes.

Moreover, the present invention is not limited to application to NAND type flash memories. Not only NAND type flash memories but also NOR type flash memories for example can face decreased reliability of the memory due to repetitive programming and erasing operations. Further, this is not the case only with flash memories, but the situation is the same among other types of data memory devices such as ferroelectric memories, magnetic memories, hard disk drive devices, etc. That is, even when applied to any other than NAND type flash memories, the present invention can as much as possible reduce a physical impact on the memory cells, i.e., memory elements, and hence improve the reliability of the memory devices and prolong the life of the memory devices.

What is claimed is:

1. A data memory device, comprising:
a memory element array including an array of a plurality of memory elements each capable of storing M-value data (M being a natural number not smaller than 2);
a data storing unit configured to temporarily store program data to be programmed into the memory elements; and
a data processing unit configured to execute a data process on the program data,
the M-value data being composed of first data to M-th data, the first data being data giving a largest physical impact on the memory elements when programmed thereinto among the first data to the M-th data,
the data processing unit being configured to be able to execute a data process on an aggregate of the program data stored in the data storing unit, and the program data to be programmed into memory elements,
the data process being conducted to determine which of the first data to the M-th data is least existing data, the number of pieces of the least existing data being the smallest in the aggregate of the program data,
the data process including a first data process and a second data process,
the first data process being performed, when the least existing data is data other than the first data, to replace the least existing data included in the aggregate of the program data with the first data and replacing the first data included in the aggregate of the program data with the least existing data; and
the second data process being performed, when the least existing data is the first data, to maintain the aggregate of the program data as it is without executing any data replacement thereon.

2. The data memory device according to claim 1,
wherein data is defined such that data with larger M gives a smaller physical impact on the memory elements, and
when plural ones of data among the first data to the M-th data correspond to the least existing data, the data processing unit executes the first data process by defining data giving a smallest physical impact on the memory elements as the least existing data.

3. The data memory device according to claim 1, comprising a parity data generating unit configured to, when the first data process has been executed, generate parity data for the aggregate of the program data for specifying whether the first data process has been executed thereon or not, and a type of the least existing data therein.

4. The data memory device according to claim 3, further comprising a parity data storing unit configured to store the parity data.

5. The data memory device according to claim 3,
wherein when the least existing data is the first data, the parity data generating unit generates the M-th data as the parity data, and
when the least existing data is the M-th data, the parity data generating unit generates the first data as the parity data.

6. The data memory device according to claim 3,
wherein when the least existing data is P-th data (where 1<P<M) among the first data to the M-th data, the parity data generating unit generates (M−P+1)th data as the parity data.

7. The data memory device according to claim 1, further comprising a data dividing process unit configured to divide externally supplied data into a plurality of aggregates including the aggregate of the program data.

8. The data memory device according to claim 7, further comprising a parity data generating unit configured to, when the first data process has been executed, generate parity data for each of the aggregates for specifying whether the first data process has been executed thereon or not, and a type of the least existing data therein.

9. The data memory device according to claim 8, further comprising a parity data storing unit configured to store the parity data.

10. A method of programming data into a data memory device including a memory element array including an array of a plurality of memory elements each capable of storing M-value data (where M is a natural number not less than 2),
the M-value data being including first data to M-th data, the first data being data giving a largest physical impact on the memory elements when programmed thereinto among the first data to the M-th data,
the method comprising:
temporarily storing program data to be programmed into the memory elements;
determining which of the first data to the M-th data is least existing data, the number of pieces of the least existing data being the smallest in an aggregate of the program data;
when the least existing data is data other than the first data, replacing the least existing data included in the aggregate of the program data with the first data and replacing the first data included in the aggregate of the program data with the least existing data; and
when the least existing data is the first data, maintaining the aggregate of the program data as it is without executing any data replacement thereon.

11. The method of programming according to claim 10,
wherein data is defined such that data with larger M gives a smaller physical impact on the memory elements, and
when plural ones of data among the first data to the M-th data correspond to the least existing data, executing a data process by defining data giving a smallest physical impact on the memory elements as the least existing data.

12. The method of programming according to claim 10, comprising generating parity data for the aggregate of the program data for specifying whether the data process has been executed thereon or not and a type of the least existing data therein.

13. The method of programming according to claim 12, comprising storing the generated parity data.

14. The method of programming according to claim 12, comprising:
generating the M-th data as the parity data when the least existing data is the first data; and
generating the first data as the parity data when the least existing data is the M-th data.

15. The method of programming according to claim 12, comprising generating (M−P+1)th data as the parity data when the least existing data is P-th data (where 1<P<M) among the first data to the M-th data.

16. The method of programming according to claim 10, comprising dividing an externally supplied data into a plurality of such aggregates including the aggregate of the program data.

17. The method of programming according to claim 16, comprising generating parity data for each of the aggregates for specifying whether the data process has been executed thereon or not and a type of the least existing data therein.

18. The method of programming according to claim 17, comprising storing the parity data.
